(19) United States
(12) Patent Application Publication
(10) Pub. No.: US 2026/0237056 A1
(43) Pub. Date: Aug. 13, 2026

(54) METHOD AND APPARATUS WITH NEURAL NETWORK POSITIONAL ENCODING

(71) Applicant: Samsung Electronics Co., Ltd., Suwon-si (KR)

(72) Inventors: Yun S PARK, Suwon-si (KR); Ho-Kuen SHIN, Suwon-si (KR); Hunsik SHIN, Suwon-si (KR); Sungjoo SUH, Suwon-si (KR)

(73) Assignee: Samsung Electronics Co., Ltd., Suwon-si (KR)

(21) Appl. No.: 19/535,366

(22) Filed: Feb. 10, 2026

(30) Foreign Application Priority Data
Feb. 11, 2025 (KR) 10-2025-0017500

(51) Int. Cl. G06T 7/00

(52) U.S. Cl. CPC G06T 7/001; G06T 2207/20084; G06T 2207/30148

(57) ABSTRACT

A processor-implemented method including generating chip-specific data for respective chips by separating image data including a plurality of chips formed on a wafer, generating a plurality of chip embeddings by performing flattening and linear projection on the chip-specific data, extracting respective polar coordinates of a chip-specific positions from within image data of a wafer, generating a plurality of positional embeddings from a plurality of polar coordinates, and combining the plurality of positional embeddings and the plurality of chip embeddings, respectively to input the combination into a neural network.

### CROSS-REFERENCE TO RELATED APPLICATION

This application claims priority to and the benefit of Korean Patent Application No. 10-2025-0017500 filed with the Korean Intellectual Property Office on Feb. 11, 2025, the entire contents of which is incorporated herein by reference.

### BACKGROUND

### (a) Field

The present disclosure relates to a method and apparatus for providing positional encoding to a neural network.

### (b) Description of the Related Art

In typical semiconductor manufacturing processes, process variables can be measured in chips on a wafer through the use of various measuring equipment. The position and number of chips measured on the wafer may vary depending on a measurement recipe for that wafer. For example, in addition to a typical 13-point measurement method targeting a chip at a fixed position, the number and position of measurements can be variably set to 17-points, 22-points, etc. according to the type of measurement recipe being applied in that wafer's manufacturing process. However, these variable measurement methods can result in inconsistent chip positional information for the wafer, which can affect the analysis and interpretation of measurement data. For example, the coordinates of critical dimension (CD) and optical critical dimension (OCD) data may differ by ±1 unit on the X-axis and Y-axis.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including generating chip-specific data for respective chips by separating image data including a plurality of chips formed on a wafer, generating a plurality of chip embeddings by performing flattening and linear projection on the chip-specific data, extracting respective polar coordinates of a chip-specific positions from within the image data of the wafer, generating a plurality of positional embeddings from a plurality of polar coordinates, and combining the plurality of positional embeddings and the plurality of chip embeddings, respectively to input the combination into a neural network.

The extracting may include determining a reference position of the wafer in the image data and determining positions of the plurality of chips with respect to the reference position in polar coordinate values.

The determining the reference position may include determining a first pixel in the image data, the first pixel representing the wafer corresponding to the reference position and the determining the positions of the plurality of chips in the polar coordinate values may include determining a second pixel corresponding to the positions of the plurality of chips with respect to the reference position and determining the polar coordinate values based on a first value of the first pixel and a second value of the second pixel.

The determining the reference position may include determining a first serial number assigned to a reference chip, the reference chip of the plurality of chips corresponding to the reference position and the determining the positions of the plurality of chips in the polar coordinate values may include determining a second serial number assigned to the plurality of chips and determining the polar coordinate values based on the first serial number and the value of the second serial number.

The generating the plurality of positional embeddings may include generating the plurality of positional embeddings according to

$$PE ( ( r , θ ) , 4 t to 4 t + 3 ) = [ sin ( \frac{r}{10 \; 4 t / ⌊ \frac{d}{4} ⌋} ) , cos ( \frac{r}{10 \; 4 t / ⌊ \frac{d}{4} ⌋} ) , sin ( \frac{θ}{10 \; 4 t / ⌊ \frac{d}{4} ⌋} ) , cos ( \frac{θ}{10 \; 4 t / ⌊ \frac{d}{4} ⌋} ) ] ,$$

where r and θ are polar coordinates, t is one of a channel index or a frequency index of the positional embedding, and d is an embedding dimension.

The generating the plurality of positional embeddings may include generating the plurality of positional embeddings according to PE=ρ*PE(r)+(1−ρ)*PE(θ), where PE(r) is a first positional embedding generated based on r among the polar coordinates, PE(θ) is a second positional embedding generated based on θ among the polar coordinates, and ρ is a real number greater than or equal to 0 and smaller than or equal to 1.

The generating the plurality of positional embeddings may include generating the plurality of positional embeddings according to PE=concat(PE(r), PE(θ)), where length(PE(r)=ρ*length(PE), and length(PE(θ)=(1−ρ)*length(PE), where PE(r) is a third positional embedding generated based on r among the polar coordinates, PE(θ) is a fourth positional embedding generated based on θ among the polar coordinates, and ρ is a real number greater than or equal to 0 and smaller than or equal to 1.

The neural network may include a transformer and the combining the plurality of positional embeddings and the plurality of chip embeddings may include combining the plurality of positional embeddings and the plurality of chip embeddings, respectively, to input the combination into an encoder of the transformer.

The method may include obtaining a yield of the wafer by using the transformer.

In a general aspect, here is provided a processor-implemented method including extracting respective polar coordinates of a chip-specific positions from within image data of a wafer, generating a plurality of positional embeddings from the respective polar coordinates, combining the plurality of positional embeddings and a plurality of manufacture data embeddings related to a manufacturing process of a semiconductor device, respectively, to input the combination into a neural network, and determining, by the neural network, whether the semiconductor device is defective by using the neural network.

The extracting may include determining a reference position of the wafer from the image data and determining positions of a plurality of chips of the wafer with respect to the reference position in polar coordinate values, and the plurality of manufacture data embeddings may include a process variable value and equipment information for the manufacturing process.

The determining the reference position may include determining a first pixel in the image data, the first pixel representing the wafer corresponding to the reference position and the determining the positions of the plurality of chips in the polar coordinate values may include determining a second pixel corresponding to the positions of the plurality of chips with respect to the reference position and determining the polar coordinate values based on a first value of the first pixel and a second value of the second pixel.

The determining the reference position may include determining a first serial number assigned to a reference chip of the plurality of chips, the reference chip corresponding to the reference position and the determining the positions of the plurality of chips in the polar coordinate values may include determining a second serial number assigned to the plurality of chips and determining the polar coordinate values based on the first serial number and the value of the second serial number.

In a general aspect, here is provided an apparatus including one or more processors, one or more memory devices, and instructions loaded on the one or more memory devices are executed through the one or more processors, so that the one or more processors is configured to generate chip-specific data for respective chips by separating image data including a plurality of chips formed on a wafer, generate a plurality of chip embeddings by performing flattening and linear projection from the chip-specific data, extract chip-specific positions in the wafer into a plurality of polar coordinates, generate a plurality of positional embeddings from the plurality of polar coordinates, and combine the plurality of positional embeddings and the plurality of chip embeddings, respectively, to input the combination into a neural network.

The extracting may include determining a reference position of the wafer in the image data and determining positions of the plurality of chips with respect to the reference position in polar coordinate values.

The determining the reference position may include determining a first pixel in the image data, the first pixel representing the wafer corresponding to the reference position and the determining the positions of the plurality of chips in the polar coordinate values may include determining a second pixel corresponding to the positions of the plurality of chips with respect to the reference position and determining the polar coordinate values based on a first value of the first pixel and a second pixel value of the second pixel.

The determining the reference position may include determining a first serial number assigned to a reference chip of the plurality of chips, the reference chip corresponding to the reference position and the determining the positions of the plurality of chips in the polar coordinate values may include determining a second serial number assigned to the plurality of chips and determining the polar coordinate values based on the first serial number and the value of the second serial number.

The generating the plurality of positional embeddings may include generating the plurality of positional embeddings according to

$$PE ( ( r , θ ) , 4 t to 4 t + 3 ) = [ sin ( \frac{r}{10 \; 4 t / ⌊ \frac{d}{4} ⌋} ) , cos ( \frac{r}{10 \; 4 t / ⌊ \frac{d}{4} ⌋} ) , sin ( \frac{θ}{10 \; 4 t / ⌊ \frac{d}{4} ⌋} ) , cos ( \frac{θ}{10 \; 4 t / ⌊ \frac{d}{4} ⌋} ) ] ,$$

where r and θ are the polar coordinates, t is one of a channel index or a frequency index of the positional embedding, and d is an embedding dimension.

The generating the plurality of positional embeddings may include generating the plurality of positional embeddings according to PE=ρ*PE(r)+(1−ρ)*PE(θ), where PE(r) is a first positional embedding generated based on r among the polar coordinates, PE(θ) is a second positional embedding generated based on θ among the polar coordinates, and ρ is a real number greater than or equal to 0 and smaller than or equal to 1.

The generating the plurality of positional embeddings may include generating the plurality of positional embeddings according to

$$PE = con c a t ( P E ( r ) , PE ( θ ) ) ,$$

$$where length ( PE ( r ) = ρ * length ( PE ) , and$$

$$length ( PE ( θ ) = ( 1 - ρ ) * length ( PE ) ,$$

where PE(r) is a third positional embedding generated based on r among the polar coordinates, PE(θ) is a fourth positional embedding generated based on θ among the polar coordinates, and ρ is a real number greater than or equal to 0 and smaller than or equal to 1.

### BRIEF DESCRIPTION OF THE DRAWINGS

FIG. 1 illustrates an example apparatus with positional encoding according to one or more embodiments.

FIGS. 2 and 3 illustrate example wafers with chips according to one or more embodiments.

FIGS. 4 and 5 illustrate example processes with chop position determination according to one or more embodiments.

FIG. 6 illustrates an example method with positional encoding for a neural network according to one or more embodiments.

FIG. 7 illustrates an example apparatus with positional encoding for a neural network according to one or more embodiments.

FIG. 8 illustrates an example apparatus with positional encoding for a neural network according to one or more embodiments.

FIG. 9 illustrates an example method with positional encoding for a neural network according to one or more embodiments.

FIG. 10 illustrates an example electronic device according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example”, “embodiment”, and “example embodiment” herein have a same meaning (e.g., the phrasing ‘in an or one example’ has a same meaning as ‘in an or one embodiment” and ‘in an or one example embodiment’), and “one or more examples” has a same meaning as “one or more embodiments” and “one or more example embodiments”. Still further, each of multiple or all separately described an/one “example”, “embodiment”, “example embodiment”, as well as “examples”, “embodiments”, “example embodiments”, herein may be included, in combination, in a same embodiment in any combination.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

Equations represented in this specification may be represented in the form of data, so as to be stored in a storage medium that can be accessed by a computing device or an apparatus for providing positional encoding to a neural network, which is configure to perform a method for providing positional encoding to a neural network, or may be stored in a remote computing device or cloud environment. The computing device or an apparatus for providing positional encoding to a neural network, which is configured to perform a method for providing positional encoding to a neural network may, in order to access that equations, load them on the memory from these storage devices, or may load them in the memory by being provided from the remote computing device or cloud environment through a network.

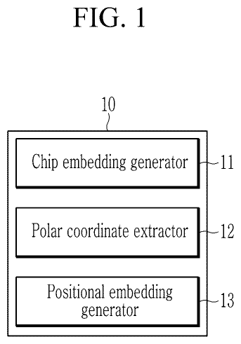

FIG. 1 illustrates an example apparatus with positional encoding according to one or more embodiments.

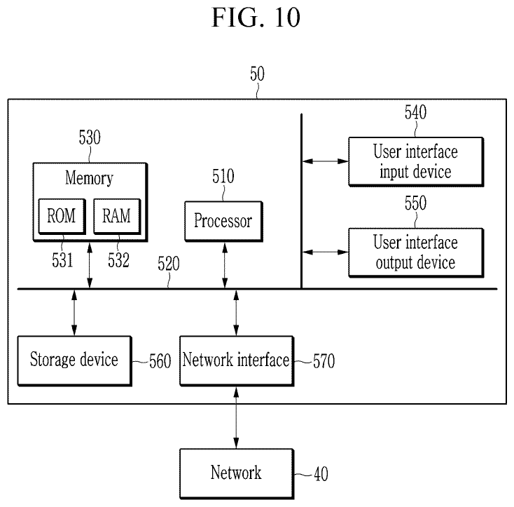

Referring to FIG. 1, in a non-limiting example, an apparatus 10 for providing positional encoding to a neural network may execute the program codes or instructions stored in one or more memory devices through one or more processors. For example, the apparatus 10 may be implemented as an electronic device 50 described in greater detail below with reference to FIG. 10. In this case, one or more processors may correspond to the processor 510 of the electronic device 50, and one or more memory devices may correspond to the memory 520 of the electronic device 50. The program codes or instructions may be executed by the one or more processors, to provide positional encoding to a neural network.

The apparatus 10 may include a chip embedding generator 11, polar coordinate extractor 12 and a positional embedding 13.

In an example, the chip embedding generator 11 may separate a plurality of chip-specific data determined with respect to respective chips formed on a wafer. The chips typically form a lattice arrangement on a wafer, and the chips may be disposed to have the same size and interval. The arrangement of chips may be symmetrical based on the center of the wafer, or may be varied depending on specific process conditions. In particular, the shape in which chips are disposed on a wafer may also vary depending on processes being used, and for example, during the process of performing the exposure process in the unit of shots, chips within each shot are disposed while maintaining a regular interval, but overall chip arrangement on the wafer may be formed irregularly depending on edge of the wafer or specific process variables.

In an example, chip-specific data may include an image data correspond to a single chip. That is, the chip embedding generator 11 may separate a plurality of image data, the separating being determined with respect to respective chips formed on wafer into the plurality of chip-specific data. That is, the chip-specific data is formed by separating respective chips found on a wafer. Thus, the respective chips in the wafer are separated into the chip-specific data. In particular, the chip embedding generator 11 may generate chip-specific data for respective chips by separating the image data including a plurality of chips that are formed on the wafer. For example, the chip embedding generator 11 may recognize X, Y coordinates and chip boundaries of individual chips based on the lattice pattern in which the chips are formed on the wafer, and may extract a portion correspond to a specific chip from an entire wafer image.

The chip embedding generator 11 may generate a plurality of chip embeddings by performing flattening and linear projection with respect to each of the plurality of chip-specific data. Here, the flattening may refer to a process of, when the chip-specific data is in the form of, for example, 2D image data, converting that image data to a 1D vector. For example, a chip image data of H×W size may be converted into a vector of (H×W) length through flattening. Meanwhile, the linear projection may refer to a process of converting the planarized chip-specific data vector to a vector of a fixed dimension appropriate for the embedding space of a neural network. Through this, the chip-specific data may be converted to a chip embedding vector of a fixing dimension that can be learned by the neural network. As such, the generated plurality of chip embeddings may be coupled to a plurality of positional embeddings described later, so that the positional information of chips may be more precisely reflected.

The polar coordinate extractor 12 may extract chip-specific positions within the wafer, in a plurality of polar coordinates. The polar coordinates may refer to representing a position based on a center, by using a radial distance r and a polar angle θ. That is, the polar coordinate extractor 12 may determine a reference position of the wafer (e.g., the center position of the wafer), and may determine positions of a plurality of chips with respect to the reference position in polar coordinate values (r, θ).

In an example, the polar coordinate extractor 12 may extract the polar coordinates with respect to chip-specific positions by using pixel information. Specifically, the polar coordinate extractor 12 may determine a first pixel corresponding to the reference position from a wafer image representing the wafer. Here, the first pixel may be represented as Cartesian coordinate values. For example, the first pixel may be determined as a central point of a rectangle containing the reference position in horizontal and vertical directions, and in other examples, may be determined as one of the vertices of a quadrangle chip containing the reference position (e.g., a vertex at the upper left end).

In addition, the polar coordinate extractor 12 may determine a second pixel corresponding to the positions of the plurality of chips with respect to the reference position. Here, the second pixel may also be represented as Cartesian coordinate values. For example, the second pixel may be determined as a central point of a quadrangle chip for determining the second pixel in horizontal and vertical directions, and in some other embodiments, may be determined as one of the vertices of a quadrangle chip to determine the second pixel (e.g., a vertex at the upper left end).

Subsequently, the polar coordinate extractor 12 may determine the polar coordinate values based on the value of the first pixel and the value of the second pixel. For example, when it is determined that the coordinates of the first pixel is (xᵣ, yᵣ), and the coordinates of the second pixel is (x_{c}, y_{c}), the polar coordinate extractor 12 may determine the polar coordinate values, through operations such as r=√((x_{c}−xᵣ)²+(y_{c}−yᵣ)²), and θ=tan⁻¹((y_{c}−yᵣ)/(x_{c}−xᵣ)).

In an example, the polar coordinate extractor 12 may extract the polar coordinates with respect to chip-specific positions by using serial numbers assigned to respective chips on the wafer. Specifically, the polar coordinate extractor 12 may determine a first serial number assigned to the chip corresponding to the reference position on the wafer. Here, the first serial number may include a value assigned in an X axis direction, and a value assigned in a Y axis direction, with respect to a chip on a wafer. For example, the first serial number may have a form such as “35, 53”, and may specify one chip among chips having that value, where that one chip is arranged on the wafer. In addition, the polar coordinate extractor 12 may determine a second serial number assigned to the plurality of chips. Here, the second serial number may also include a value assigned in the X axis direction, and a value assigned in the Y axis direction, with respect to a chip on a wafer. For example, the second serial number may have a form such as “36, 52”, and may specify another chip among the chips which has that value and is also arranged on the wafer. Subsequently, the polar coordinate extractor 12 may determine the polar coordinate values based on the first serial number and the value of the second serial number. The first serial number and the second serial number are numbers uniquely assigned to respective chips on one wafer, and relative positions between chips on the wafer may be identified based on these numbers.

In an example, the positional embedding generator 13 may generate the plurality of positional embeddings from the plurality of polar coordinates through a predetermined operation, so that the neural network model may learn the polar coordinates-based positional information.

In an example, the positional embedding generator 13 may generate the plurality of positional embeddings according to Equation 1 below.

$$PE ( ( r , θ ) , 4 t to 4 t + 3 ) = [ sin ( \frac{r}{10 \; 4 t / ⌊ \frac{d}{4} ⌋} ) , cos ( \frac{r}{10 \; 4 t / ⌊ \frac{d}{4} ⌋} ) , sin ( \frac{θ}{10 \; 4 t / ⌊ \frac{d}{4} ⌋} ) , cos ( \frac{θ}{10 \; 4 t / ⌊ \frac{d}{4} ⌋} ) ] \qquad Equation 1$$

Here, r and θ may be polar coordinates, t may be a channel index or a frequency index of the positional embedding, and d may be an embedding dimension. That is, the positional embedding generator 13 may convert the distance r from the reference position to the chip, among the polar coordinate values of the chip within the wafer, in various frequency scales, to reflect various space resolutions. For example, in the case of a low frequency, the neural network can be made to learn global positional information, and in the case of a high frequency, the neural network can be made to lean detailed positional information. Meanwhile, by applying a sine function and a cosine function, the position relationship may be represented periodically. In the same way, the polar angle θ may also be converted in multiple frequency scales, and accordingly, the neural network may effectively recognize in which direction the chip is located on the wafer.

In an example, the positional embedding generator 13 may generate the plurality of positional embeddings according to Equation 2 below.

$$P E = ρ * P E ( r ) + ( 1 - ρ ) * P E ( θ ) \qquad Equation 2$$

Here, PE(r) may be a positional embedding generated based on r among the polar coordinates, PE(θ) may be a positional embedding generated based on θ among the polar coordinates, and, and ρ may be a real number greater than or equal to 0 or smaller than or equal to 1. That is, the positional embedding generator 13 may generate a positional embedding in a weighted sum method, which can adjust the contribution of r and θ in the polar coordinates. Through this, the positional embedding can be generated by flexibly combining the radius and polar angle information depending on the characteristics of the chip positional information. Specifically, when ρ is 1, the positional embedding may be determined by the positional embedding generated based on r, and when ρ is 0, the positional embedding may be determined by the positional embedding generated based on θ, and when 0<ρ<1, the positional embedding may be determined as a positional embedding having further higher consistency, by combining two types of information.

In an example, the positional embedding generator 13 may generate the plurality of positional embeddings according to Equation 3 below.

$$PE = co n c a t ( P E ( r ) , PE ( θ ) ) , \qquad Equation 3$$

$$where length ( PE ( r ) = ρ * length ( PE ) , and$$

$$length ( PE ( θ ) = ( 1 - ρ ) * length ( PE )$$

Here, PE(r) may be a positional embedding generated based on r among the polar coordinates, PE(θ) may be a positional embedding generated based on θ among the polar coordinates, and ρ may be a real number greater than or equal to 0 or smaller than or equal to 1. That is, the positional embedding generator 13 may connect the positional embedding generated based on r and the positional embedding generated based on θ, and may dynamically adjust its ratio. The length of the final embedding vector may be maintained as length(PE), and the proportion of radius and polar angle information may be dynamically adjusted according to the value of ρ.

The positional embedding generator 13 may combine the generated plurality of positional embeddings, and the plurality of chip embeddings generated by the chip embedding generator 11, respectively, and input the combination into the neural network. In an example, the neural network may be a transformer. The positional embedding generator 13 may combine the plurality of positional embeddings and the plurality of chip embeddings, respectively, and input the combination into the encoder of the transformer. Accordingly, the transformer can be made to simultaneously reflect the spatial positional information of the chip within the wafer and the feature information of an individual chip. The method in which the plurality of positional embeddings and the plurality of chip embeddings are combined may be implemented in various methods such as concatenation, addition, or the like.

A final input vector combining the positional embedding and the chip embedding may be transferred to an input token of a transformer encoder, and a multi-head attention operation may be applied. The transformer encoder may perform a self-attention operation so that the relationship and spatial pattern between respective chips can be learned, and through this, the mutual relationship and process pattern between the chips within the wafer may be extracted. Through this, compared to the case that the conventional 1 dimensional or a Cartesian coordinate system-based 2-dimension positional encoding is used for the neural network, for example, the transformer, as a polar coordinate system-based positional encoding is used, the spatial disposal and properties of the chips on the wafer can be more effectively represented, and therefore, higher consistency can be provided in an application such as semiconductor process optimization, yield prediction, defect detection. For example, in the case of Single Bit Disturb (SBD) among the defects which can possibly be generated during the production of the dynamic random-access memory (DRAM), the distribution of fail bits tends to vary away from the center of the wafer, but in the conventional 1 dimensional or the Cartesian coordinate system-based 2-dimension positional encoding, it is difficult to reflect such wafer-specific properties.

In an example, by applying a polar coordinate system-based positional encoding, information on radial distance from the wafer center may be directly utilized in a semiconductor field work using an artificial intelligence model. This enables modeling with higher consistency than in cases involving modeling while using typical Cartesian coordinate system-based positional encoding.

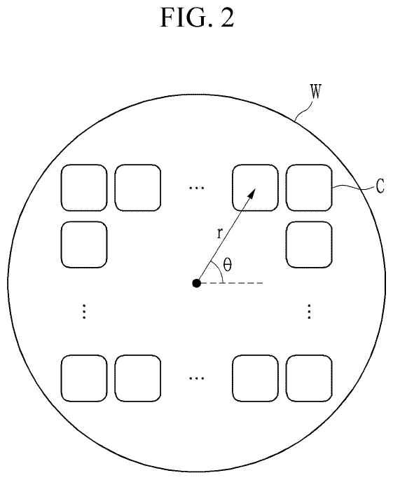

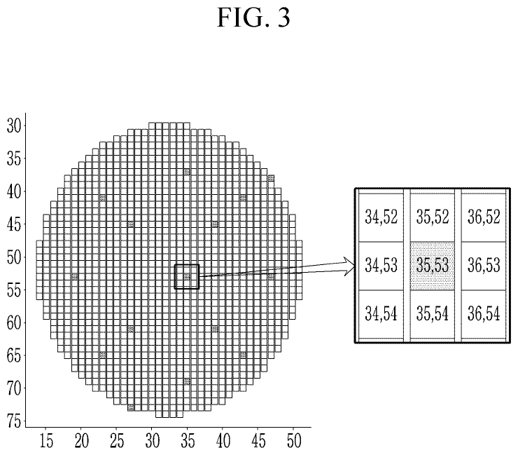

FIGS. 2 and 3 illustrate example wafers with chips according to one or more embodiments.

Referring to FIG. 2, in a non-limiting example, a position of each chip C within a wafer W may be extracted in polar coordinates, and the polar coordinates may include the radial distance r and the value of the polar angle θ in the position of the chip C, based on the reference position, for example, the center. In an example, the polar coordinates with respect to the position of respective chip C may be extracted based on pixels, and in some other embodiments, the polar coordinates with respect to the position of respective chip C may be extracted by using serial numbers assigned to respective chips on the wafer.

Referring to FIG. 3, in a non-limiting example, for respective chips C arranged on the wafer W, a first value assigned in the X axis direction is assigned, and a second value assigned in the Y axis direction is assigned. Referring to the enlarged portion, a serial number of the chip C located at the center may be “35, 53”, and serial numbers of chips arranged around that chip C may be “34, 52”, “34, 53”, “34, 54”, “35, 52”, “35, 54”, “36, 52”, “36, 53”, “36, 54”. Based on the values of such serial numbers, the relative positions between chips on the wafer may be identified, and accordingly, the polar coordinate values may be determined.

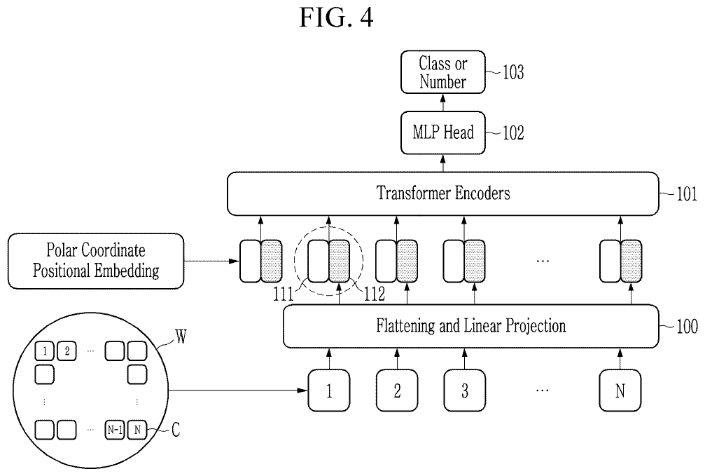

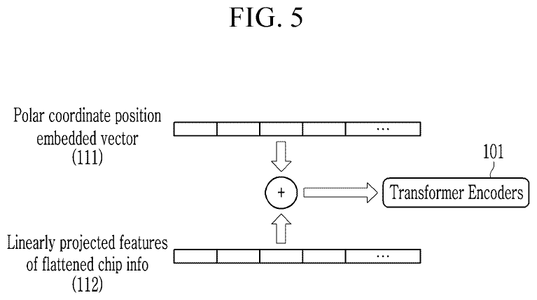

FIGS. 4 and 5 illustrate example processes with chop position determination according to one or more embodiments.

Referring to FIGS. 4, in a non-limiting example, the chip embedding generator 11 may separate the plurality of chip-specific data (1, 2, . . . . N) determined for respective chips C formed on the wafer W. The chip embedding generator 11 may convert the plurality of chip-specific data (1, 2, . . . . N) to the plurality of chip embeddings 112, through the flattening and the linear projection layer 100. Meanwhile, the polar coordinate extractor 12 may extract the chip-specific position within the wafer W in the plurality of polar coordinates, and the positional embedding generator 13 may generate the plurality of positional embeddings 111 from the plurality of polar coordinates through a predetermined operation, so that the neural network model may learn the polar coordinates-based positional information.

The positional embedding generator 13 may combine the generated plurality of positional embeddings 111, and the plurality of chip embeddings 112 generated by the chip embedding generator 11, respectively, and input the combination into the neural network. Specifically, the final input vector combining the plurality of chip embeddings 112 generated by the chip embedding generator 11 may be transferred to a transformer encoder 101, and thereafter, through a multilayer perceptron (MLP) head layer 102 and an inference layer 103, semiconductor process optimization, yield prediction, defect detection, or the like may be implemented. Referring to FIG. 5, in a non-limiting example, a method in which the plurality of positional embeddings 111 and the plurality of chip embeddings 112 are combined may be implemented in various methods such as concatenation, addition, or the like, is illustrated.

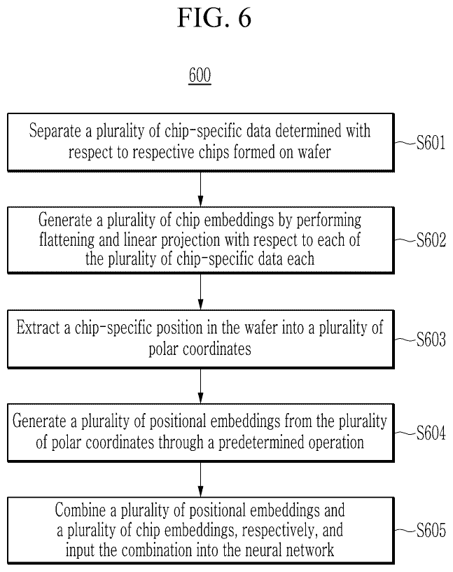

FIG. 6 illustrates an example method with positional encoding for a neural network according to one or more embodiments.

Referring to FIG. 6, in a non-limiting example, a method 600 for providing positional encoding to a neural network may include step S601 of separating the plurality of chip-specific data determined with respect to respective chips formed on wafer, step S602 of generating the plurality of chip embeddings by performing the flattening and the linear projection with respect to each of the plurality of chip-specific data, step S603 of extracting a chip-specific position on wafer as the plurality of polar coordinates, step S604 of generating the plurality of positional embeddings from the plurality of polar coordinates through a predetermined operation, and step S605 of combining the plurality of positional embeddings and the plurality of chip embeddings, respectively, and inputting the combination into the neural network.

For further details of the method, the description of the embodiment in this specification may be referred to, and a redundant description will not be included herein.

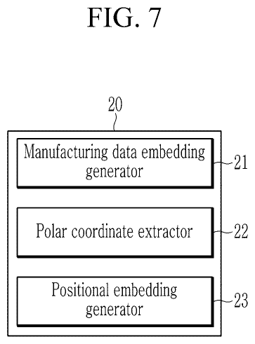

FIG. 7 illustrates an example apparatus with positional encoding for a neural network according to one or more embodiments.

Referring to FIG. 7, in a non-limiting example, an apparatus 20 for providing positional encoding to a neural network may be implemented as a computing device (e.g., electronic device 50), and may execute the program codes or instructions loaded on one or more memory devices through one or more processors.

The apparatus 20 may include manufacture data embedding generator 21, polar coordinate extractor 22 and a positional embedding generator 23.

In an example, the manufacture data embedding generator 21 may obtain a plurality of manufacture data embeddings including a process variable value and equipment information related to manufacturing of a semiconductor device. The process variable refers to a factor in the manufacturing process of the semiconductor device, which determines the performance and quality of the wafer and chips, and may be measured in various manufacturing processes. The equipment information may include information on manufacturing equipment used in each process. For example, the semiconductor device may be one or more of various semiconductor devices, including, for example, a DRAM.

In an example, the polar coordinate extractor 22 may extract the chip-specific positions within the wafer, in the plurality of polar coordinates. For details of the polar coordinate extractor 22, the description on the polar coordinate extractor 12 may be referred to, and a redundant description will not be included herein.

In an example, the positional embedding generator 23 may generate the plurality of positional embeddings from the plurality of polar coordinates through a predetermined operation, so that the neural network model may learn the polar coordinates-based positional information. For details of the positional embedding generator 23, to the extent that is not contradictory to the present example, the description on the positional embedding generator 13 may be referred to, and a redundant description will not be included herein.

The positional embedding generator 23 may combine the generated plurality of positional embeddings, and the plurality of manufacture data embeddings generated by the manufacture data embedding generator 21, respectively, and input the combination into the neural network. In an example, the neural network may be a transformer. The positional embedding generator 23 may combine the plurality of positional embeddings and the plurality of manufacture data embeddings, respectively, and input the combination into the encoder of the transformer. Accordingly, the transformer can be made to simultaneously reflect the spatial positional information of the chip within the wafer, and a process variable value and equipment information related to manufacturing of a semiconductor device. The method in which the plurality of positional embeddings and the plurality of manufacture data embeddings are combined may be implemented in various methods such as concatenation, addition, or the like.

The final input vector combining the positional embedding and the manufacture data embedding may be transferred to the input token of the transformer encoder, and a multi-head attention operation may be applied. The transformer encoder may perform a self-attention operation so that the relationship and spatial pattern between respective chips can be learned, and through this, the mutual relationship and process pattern between the chips within the wafer may be extracted. Through this, by considering the spatial disposal and properties of the chips, high performance may be provided in the defect detection of the semiconductor device, for example, DRAM.

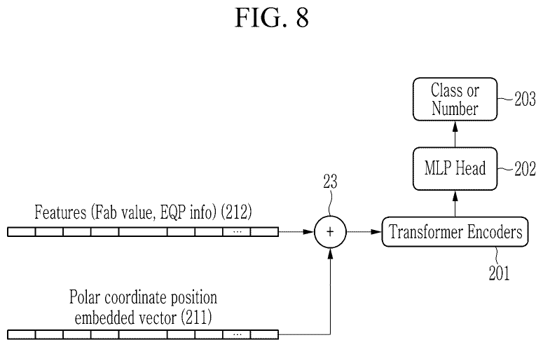

FIG. 8 illustrates an example apparatus with positional encoding for a neural network according to one or more embodiments.

Referring to FIG. 8, in a non-limiting example, the positional embedding generator 23 may combine the generated plurality of positional embeddings 211, and a plurality of manufacture data embeddings 212 generated by the manufacture data embedding generator 21, respectively, and input the combination into the neural network. Specifically, the final input vector combining the plurality of manufacture data embeddings 212 generated by the manufacture data embedding generator 21 may be transferred to a transformer encoder 201, and thereafter, through a multilayer perceptron head layer 202 and an inference layer 203, defect detection of the semiconductor device, for example, DRAM, may be implemented. As illustrated in the drawings, the method in which the plurality of positional embeddings 211 and the plurality of manufacture data embeddings 212 are combined may be implemented in various methods such as concatenation, addition, or the like.

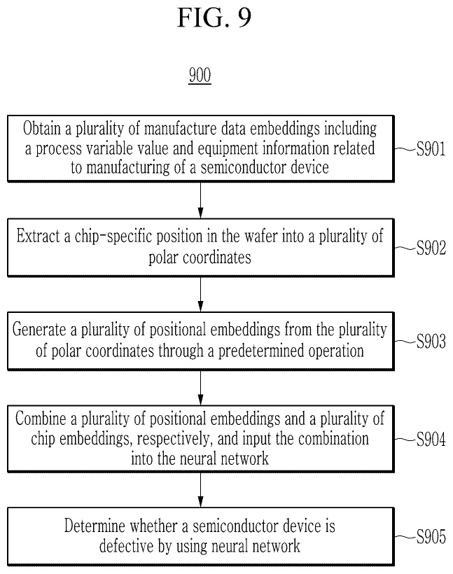

FIG. 9 illustrates an example method with positional encoding for a neural network according to one or more embodiments.

Referring to FIG. 9, in a non-limiting example, a method 900 for providing positional encoding to a neural network may include step S901 of obtaining the plurality of manufacture data embeddings including a process variable value and equipment information related to manufacturing of a semiconductor device, step S902 of extracting a chip-specific position in the wafer into the plurality of polar coordinates, step S903 of generating the plurality of positional embeddings from the plurality of polar coordinates through a predetermined operation, step S904 of combining the plurality of positional embeddings and the plurality of manufacture data embeddings, respectively, and inputting the combination into the neural network, and step S905 of determining whether the semiconductor device is defective by using the neural network.

For further details of the method, the description of the above examples in this specification may be referred to, and a redundant description will not be included herein.

FIG. 10 illustrates an example electronic device according to one or more embodiments.

Referring to FIG. 10, in a non-limiting example, a method and apparatus for providing positional encoding to a neural network may be implemented by using the electronic device 50. The electronic device 50 may be implemented as various types of electronic devices, servers, or similar devices, and its function may be implemented through a combination of software and hardware.

The electronic device 50 may include at least one of the processor 510, a memory 530, a user interface input device 540, a user interface output device 550, and a storage device 560 in communication through a bus 520. The electronic device 50 may also include a network interface 570 electrically connected to the network 40. The network interface 570 may transmit or receive signals with other entities through the network 40.

The processor 510 may be configured to execute programs or applications to configure the processor 510 to control the electronic device 50 to perform one or more or all operations and/or methods involving providing of positional encoding to a neural network. The processor 510 may be implemented as various types of computing devices, such as a micro controller unit (MCU), an application processor (AP), a central processing unit (CPU), a graphic processing unit (GPU), a natural processing unit (NPU), and a quantum processing unit (QPU). The processor 510 is a semiconductor device that executes instructions stored in the memory 530 or the storage device 560, and may play a key role in the system. Program codes and data stored in the memory 530 or the storage device 560 instruct the processor 510 to perform a specific task, thereby enabling the overall operation of the system. The processor 510 may be configured to implement various functions and methods described above with respect to FIGS. 1 to 9.

The memory 530 may include computer-readable instructions. The processor 510 may be configured to execute computer-readable instructions, such as those stored in the memory 530, and through execution of the computer-readable instructions, the processor 510 may be configured to perform one or more, or any combination, of the operations and/or methods described herein. The memory 530 and the storage device 560 may include various types of volatile or non-volatile storage media for storing and accessing data of the system. For example, the memory 530 may include a read-only memory (ROM) 531 and a random access memory (RAM) 532. In some embodiments, the memory 530 may be embedded in the processor 510, and in this case, the data transmission speed between the memory 530 and the processor 510 may be very fast. In some examples, the memory 530 may be disposed outside the processor 510, in which case the memory 530 may be connected to the processor 510 through various data buses or interfaces. This connection can be made through a variety of known members, such as a peripheral component interconnect express (PCIe) interface for high-speed data transmission or through a memory controller.

In an example, at least some of the components or functions of the method and apparatus for providing positional encoding to a neural network according to the embodiments may be implemented as a program or software executed on the electronic device 50, and the program or software may be stored in a computer-readable recording medium or storage medium. Specifically, in an example, the computer-readable recording medium or storage medium may be one writing the program for executing the steps included in the implementation of the method and apparatus for providing positional encoding to a neural network according to the examples to a computer including the processor 510 that executes the program or instruction stored in the memory 530 or the storage device 560.

In an example, at least some of the components or functions of the method and apparatus for providing positional encoding to a neural network according to the embodiments may be implemented using hardware or circuits of the electronic device 50, or may be implemented using separate hardware or circuits that may be electrically connected to the electronic device 50.

In an example, by applying a polar coordinate system-based positional encoding, information on radial distance from the wafer center may be directly utilized in a semiconductor field work using an artificial intelligence model. This enables modeling with higher consistency than when using typical Cartesian coordinate system-based positional encoding. In particular, even when typical Cartesian coordinate system positional information of a chip or shot is variable or even when the measurement position on wafer is changed, more stable positional information may be provided through the polar coordinate system-based positional encoding according to embodiments, thereby improving the reliability of model. In addition, examples of these methods may provide higher prediction accuracy in various semiconductor analysis, including wafer-level yield prediction. Furthermore, an artificial intelligence model having higher consistency may be established, and through this, the factor analysis in the process design may be performed more precisely.

The electronic devices, neural networks, memories, processors, chip embedding generator 11, polar coordinate extractor 12, positional embedding generator 13, manufacturing data embedding generator 21, polar coordinate extractor 22, positional embedding generator 23, electronic device 50, processor 510, a memory 530, user interface input device 540, user interface output device 550, storage device 560, and network interface 570 described herein, including descriptions with respect to respect to FIGS. 1-10, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-10 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
generating chip-specific data for respective chips by separating image data including a plurality of chips formed on a wafer;
generating a plurality of chip embeddings by performing flattening and linear projection on the chip-specific data;
extracting respective polar coordinates of a chip-specific positions from within the image data of the wafer;
generating a plurality of positional embeddings from a plurality of polar coordinates; and
combining the plurality of positional embeddings and the plurality of chip embeddings, respectively to input the combination into a neural network.

2. The method of claim 1, wherein the extracting comprises:
determining a reference position of the wafer in the image data; and
determining positions of the plurality of chips with respect to the reference position in polar coordinate values.

3. The method of claim 2, wherein the determining the reference position comprises:
determining a first pixel in the image data, the first pixel representing the wafer corresponding to the reference position, and
wherein the determining the positions of the plurality of chips in the polar coordinate values comprises:
determining a second pixel corresponding to the positions of the plurality of chips with respect to the reference position; and
determining the polar coordinate values based on a first value of the first pixel and a second value of the second pixel.

4. The method of claim 2, wherein the determining the reference position comprises:
determining a first serial number assigned to a reference chip, the reference chip of the plurality of chips corresponding to the reference position, and
wherein the determining the positions of the plurality of chips in the polar coordinate values comprises:
determining a second serial number assigned to the plurality of chips; and
determining the polar coordinate values based on the first serial number and the value of the second serial number.

5. The method of claim 1, wherein the generating the plurality of positional embeddings comprises:
generating the plurality of positional embeddings according to:
$$PE ( ( r , θ ) , 4 t to 4 t + 3 ) = [ sin ( \frac{r}{10 \; 4 t / ⌊ \frac{d}{4} ⌋} ) , cos ( \frac{r}{10 \; 4 t / ⌊ \frac{d}{4} ⌋} ) , sin ( \frac{θ}{10 \; 4 t / ⌊ \frac{d}{4} ⌋} ) , cos ( \frac{θ}{10 \; 4 t / ⌊ \frac{d}{4} ⌋} ) ]$$
wherein r and θ are polar coordinates, t is one of a channel index or a frequency index of the positional embedding, and d is an embedding dimension.

6. The method of claim 1, wherein the generating the plurality of positional embeddings comprises:
generating the plurality of positional embeddings according to:
$$P E = ρ * P E ( r ) + ( 1 - ρ ) * P E ( θ )$$
wherein PE(r) is a first positional embedding generated based on r among the polar coordinates, PE(θ) is a second positional embedding generated based on θ among the polar coordinates, and ρ is a real number greater than or equal to 0 and smaller than or equal to 1.

7. The method of claim 1, wherein the generating the plurality of positional embeddings comprises:
generating the plurality of positional embeddings according to:
$$PE = c o n c a t ( P E ( r ) , PE ( θ ) ) ,$$
$$where length ( PE ( r ) = ρ * length ( PE ) , and$$
$$length ( PE ( θ ) = ( 1 - ρ ) * length ( PE )$$
wherein PE(r) is a third positional embedding generated based on r among the polar coordinates, PE(θ) is a fourth positional embedding generated based on θ among the polar coordinates, and ρ is a real number greater than or equal to 0 and smaller than or equal to 1.

8. The method of claim 1, wherein the neural network comprises a transformer, and
wherein the combining the plurality of positional embeddings and the plurality of chip embeddings comprises:
combining the plurality of positional embeddings and the plurality of chip embeddings, respectively, to input the combination into an encoder of the transformer.

9. The method of claim 8, further comprising:
obtaining a yield of the wafer by using the transformer.

10. A processor-implemented method, the method comprising:
extracting respective polar coordinates of a chip-specific positions from within image data of a wafer;
generating a plurality of positional embeddings from the respective polar coordinates;
combining the plurality of positional embeddings and a plurality of manufacture data embeddings related to a manufacturing process of a semiconductor device, respectively, to input the combination into a neural network; and
determining, by the neural network, whether the semiconductor device is defective by using the neural network.

11. The method of claim 10, wherein the extracting comprises:
determining a reference position of the wafer from the image data; and
determining positions of a plurality of chips of the wafer with respect to the reference position in polar coordinate values, and
wherein the plurality of manufacture data embeddings includes a process variable value and equipment information for the manufacturing process.

12. The method of claim 11, wherein the determining the reference position comprises:
determining a first pixel in the image data, the first pixel representing the wafer corresponding to the reference position, and
wherein the determining the positions of the plurality of chips in the polar coordinate values comprises:
determining a second pixel corresponding to the positions of the plurality of chips with respect to the reference position; and
determining the polar coordinate values based on a first value of the first pixel and a second value of the second pixel.

13. The method of claim 11, wherein the determining the reference position comprises:
determining a first serial number assigned to a reference chip of the plurality of chips, the reference chip corresponding to the reference position, and
wherein the determining the positions of the plurality of chips in the polar coordinate values comprises:
determining a second serial number assigned to the plurality of chips; and
determining the polar coordinate values based on the first serial number and the value of the second serial number.

14. An apparatus, comprising:
one or more processors; and
one or more memory devices,
wherein instructions loaded on the one or more memory devices are executed through the one or more processors, so that the one or more processors is configured to:
generate chip-specific data for respective chips by separating image data including a plurality of chips formed on a wafer;
generate a plurality of chip embeddings by performing flattening and linear projection from the chip-specific data;
extract chip-specific positions in the wafer into a plurality of polar coordinates;
generate a plurality of positional embeddings from the plurality of polar coordinates; and
combine the plurality of positional embeddings and the plurality of chip embeddings, respectively, to input the combination into a neural network.

15. The apparatus of claim 14, wherein the extracting comprises:
determining a reference position of the wafer in the image data; and
determining positions of the plurality of chips with respect to the reference position in polar coordinate values.

16. The apparatus of claim 15, wherein the determining the reference position comprises:
determining a first pixel in the image data, the first pixel representing the wafer corresponding to the reference position, and
wherein the determining the positions of the plurality of chips in the polar coordinate values comprises:
determining a second pixel corresponding to the positions of the plurality of chips with respect to the reference position; and
determining the polar coordinate values based on a first value of the first pixel and a second pixel value of the second pixel.

17. The apparatus of claim 15, wherein the determining the reference position comprises:
determining a first serial number assigned to a reference chip of the plurality of chips, the reference chip corresponding to the reference position, and
wherein the determining the positions of the plurality of chips in the polar coordinate values comprises:
determining a second serial number assigned to the plurality of chips; and
determining the polar coordinate values based on the first serial number and the value of the second serial number.

18. The apparatus of claim 14, wherein the generating the plurality of positional embeddings comprises:
generating the plurality of positional embeddings according to:
$$P E ( ( r , θ ) , 4 t to 4 t + 3 ) = [ sin ( \frac{r}{10 \; 4 t / ⌊ \frac{d}{4} ⌋} ) , cos ( \frac{r}{10 \; 4 t / ⌊ \frac{d}{4} ⌋} ) , sin ( \frac{θ}{10 \; 4 t / ⌊ \frac{d}{4} ⌋} ) , cos ( \frac{θ}{10 \; 4 t / ⌊ \frac{d}{4} ⌋} ) ]$$
wherein r and θ are the polar coordinates, t is one of a channel index or a frequency index of the positional embedding, and d is an embedding dimension.

19. The apparatus of claim 14, wherein the generating the plurality of positional embeddings comprises:
generating the plurality of positional embeddings according to:
$$P E = ρ * P E ( r ) + ( 1 - ρ ) * P E ( θ )$$
wherein PE(r) is a first positional embedding generated based on r among the polar coordinates, PE(θ) is a second positional embedding generated based on θ among the polar coordinates, and p is a real number greater than or equal to 0 and smaller than or equal to 1.

20. The apparatus of claim 14, wherein the generating the plurality of positional embeddings comprises:
generating the plurality of positional embeddings according to:
$$P E = c o n c a t ( P E ( r ) , PE ( θ ) ) ,$$
$$where length ( PE ( r ) = ρ * length ( PE ) , and$$
$$length ( PE ( θ ) = ( 1 - ρ ) * length ( PE )$$
wherein PE(r) is a third positional embedding generated based on r among the polar coordinates, PE(θ) is a fourth positional embedding generated based on θ among the polar coordinates, and ρ is a real number greater than or equal to 0 and smaller than or equal to 1.
